(19) United States
(12) Patent Application Publication
(10) Pub. No.: US 2013/0264526 A1
(43) Pub. Date: Oct. 10, 2013

(54) MOLECULAR PRECURSORS AND PROCESSES FOR PREPARING COPPER INDIUM GALLIUM SULFIDE/SELENIDE COATINGS AND FILMS

(71) Applicants: Yanyan Cao, Wilmington, DE (US); John W. Catron, JR., Smyrna, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(72) Inventors: Yanyan Cao, Wilmington, DE (US); John W. Catron, JR., Smyrna, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(73) Assignee: E I DU PONT DE NEMOURS AND COMPANY, Wilmington, DE (US)

(21) Appl. No.: 13/885,105

(22) PCT Filed: Dec. 1, 2011
(86) PCT No.: PCT/US2011/062847

§ 371 Date: May 13, 2013

Related U.S. Application Data
(60) Provisional application No. 61/419,355, filed on Dec. 3, 2010.
(60) Provisional application No. 61/419,351, filed on Dec. 3, 2010.

(51) Int. Cl. H01L 31/0272

(52) U.S. Cl. CPC H01L 31/0272
USPC 252/519.4

(57) ABSTRACT

This invention relates to molecular precursors and processes for preparing coated substrates and films of copper indium gallium sulfide/selenides (CIGS/Se). Such films are useful in the preparation of photovoltaic devices. This invention also relates to processes for preparing coated substrates and for making photovoltaic devices.

### CROSS-REFERENCE TO RELATED APPLICATION

This application claims priority to U.S. Provisional Application Nos. 61/419,351 filed Dec. 3, 2010 and 61/419,355 filed Dec. 3, 2010 which are herein incorporated by reference.

### FIELD OF THE INVENTION

This invention relates to molecular precursors and processes for preparing coated substrates and films of copper indium gallium sulfide/selenides (CIGS/Se). Such films are useful in the preparation of photovoltaic devices. This invention also relates to processes for preparing coated substrates and for making photovoltaic devices.

### BACKGROUND

Semiconductors with a composition of Cu(In_{y}Ga_{1-y})(SₓSe₂₋ₓ) where O<y≦1 and 0≦×≦2, collectively known as copper indium gallium sulfide/selenide or CIGS/Se, are some of the most promising candidates for thin-film photovoltaic applications due to their unique structural and electrical properties as energy absorber materials. However, current vacuum-based techniques to make CIGS/Se thin films (e.g., thermal evaporation, sputtering) require complicated equipment and therefore tend to be expensive. In addition, materials are wasted by deposition on chamber walls, and significant energy is required to evaporate or sputter materials from a source, often onto a heated substrate.

In contrast, solution-based processes to CIGS/Se are not only less expensive than vacuum-based processes, but typically have lower energy input and can utilize close to 100% of the raw materials by precisely and directly depositing materials on a substrate. In addition, solution-based processes are readily adaptable to high-throughput roll-to-roll processing on flexible substrates.

Solution-based processes to CIGS/Se fall into three general categories: (1) Electro-, electroless and chemical bath deposition, where (electro)chemical reactions in a solution lead to the coating of an immersed substrate; (2) Particulate-based processes that use solid particles dispersed in a solvent to form an ink, which can be coated onto a substrate; and (3) Processes that coat molecular precursor solutions onto a substrate by mechanical means such as spraying or spin coating. In molecular precursor routes, the semiconductor can be synthesized in situ with direct film deposition from solution. High-boiling capping agents, which often introduce carbon-based impurities into the semiconductor film, are used in many particulate-based processes, but can be avoided in molecular precursor routes.

Molecular precursor routes to CIGS/Se have been reported using metal salts (e.g., chlorides and nitrates). For example, aqueous solutions of copper-, indium- and gallium chlorides and an excess of thio- or selenourea have been deposited via spray pyrolysis to give CIGS/Se. By mixing salt solutions with binders or chelating agents, viscosity can be increased and deposition techniques other than spraying can be employed. However, these binders and chelating agents often introduce carbon-based impurities into the CIGS/Se film. In general, incorporation of CIGS/Se films made from salt-based precursors into photovoltaic devices has led to relatively low efficiencies, possibly due to chlorine- and oxygen-based impurities.

CuInSe₂ films have been formed from a solution of Cu and In naphthenates, wherein the naphthenates are derived from an acidic fraction of processed petroleum and are composed of a mixture of organic acids. The solutions were spun-coated onto substrates, which were then then treated with a 10% mixture of hydrogen in nitrogen gas at 450° C. and then selenized in vacuum-sealed ampoules with Se vapor to give coatings with a thickness of 250 nm.

The above molecular precursor routes rely on sulfo- and seleno-ureas or thioacetamide as the chalcogen source and/or annealing in reducing H₂, H₂S, S-, or Se-containing atmosphere for chalcogenization. A molecular precursor approach to CIGS/Se involving the preparation of a solution of copper and indium chalcogenides and elemental chalcogen has been reported. However, the use of hydrazine as the solvent was required. Hydrazine is a highly reactive and potentially explosive solvent that is described in the Merck Index as a “violent poison.” Single-source organometallic precursors to CIS/Se [e.g., (Ph₃P)₂Cu(mu-SEt)₂In(SEt)₂] have been prepared and used to form CIS/Se films via spray chemical vapor deposition. However, the synthesis of these single-source precursors is involved and limits the compositional tuning of film stoichiometry. In situ synthesis of films of CIS nanocrystals has been achieved by spin-coating butylamine solutions of indium acetate, copper chloride, thiourea, and propionic acid onto a substrate and heating at 250° C. Broad lines in the x-ray diffraction (XRD) analysis confirmed the nanocrystalline nature of the film.

Hence, there still exists a need for molecular precursor routes to CIGS/Se that involve simple, low-cost, scalable materials and processes with a low number of operations that provide high-quality, crystalline CIGS/Se films with tunable composition and morphology. There also exists a need for low-temperature routes to CIGS/Se using solvents and reagents with relatively low toxicity. In addition, there is a need for inks and processes to CIGS/Se that do not require annealing in a reducing H₂, H₂S, S-, or Se-containing atmosphere, and for inks that can be coated in a single coating operation to give films of suitable thickness for thin-film photovoltaic devices.

### SUMMARY

One aspect of this invention is a molecular precursor to CIGS/Se comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof;
provided that:
   if the copper source is copper sulfide or copper selenide, and the indium source is indium sulfide or indium selenide, then the vehicle does not comprise hydrazine.

Another aspect of this invention is a process comprising disposing a molecular precursor to CIGS/Se onto a substrate to form a coated substrate, wherein molecular precursor comprises:

i) a copper source selected from the group consisting of copper complexes of nitrogen-, oxygen-, carbon-, sulfur-, or selenium-based organic ligands, copper sulfides, copper selenides, and mixtures thereof;

ii) an indium source selected from the group consisting of indium complexes of nitrogen-, oxygen-, carbon-, sulfur-, or selenium-based organic ligands, indium sulfides, indium selenides, and mixtures thereof;

iii) optionally, a gallium source selected from the group consisting of gallium complexes of nitrogen-, oxygen-, carbon-, sulfur-, or selenium-based organic ligands, gallium sulfides, gallium selenides, and mixtures thereof; and

iv) a vehicle, comprising a liquid chalcogen compound, a solvent, or a mixture thereof;

provided that if the copper source is copper sulfide or copper selenide, and the indium source is indium sulfide or indium selenide, then the vehicle does not comprise hydrazine.

Another aspect of this invention is a coated substrate comprising:
A) a substrate; and
B) at least one layer disposed on the substrate comprising a molecular precursor to CIGS/Se comprising:
   i) a copper source selected from the group consisting of copper complexes of nitrogen-, oxygen-, carbon-, sulfur-, or selenium-based organic ligands, copper sulfides, copper selenides, and mixtures thereof;
   ii) an indium source selected from the group consisting of indium complexes of nitrogen-, oxygen-, carbon-, sulfur-, or selenium-based organic ligands, indium sulfides, indium selenides, and mixtures thereof;
   iii) optionally, a gallium source selected from the group consisting of gallium complexes of nitrogen-, oxygen-, carbon-, sulfur-, or selenium-based organic ligands, gallium sulfides, gallium selenides, and mixtures thereof;
      wherein at least one of the copper or indium sources comprises complexes of nitrogen-, oxygen-, carbon-, sulfur-, or selenium-based organic ligands.

Another aspect of this invention is a process for producing a photovoltaic cell.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

Herein, grain size refers to the diameter of a grain of granular material, wherein the diameter is defined as the longest distance between two points on its surface. In contrast, crystallite size is the size of a single crystal inside the grain. A single grain can be composed of several crystals. A useful method for obtaining grain size is electron microscopy. ASTM test methods are available for determining planar grain size, that is, characterizing the two-dimensional grain sections revealed by the sectioning plane. Manual grain size measurements are described in ASTM E 112 (equiaxed grain structures with a single size distribution) and E 1182 (specimens with a bi-modal grain size distribution), while ASTM E 1382 describes how any grain size type or condition can be measured using image analysis methods.

Herein, element groups are represented using CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper indium sulfide” and “CIS” refer to CuInS₂. “Copper indium selenide” and “CIS—Se” refer to CuInSe₂. “Copper indium sulfide/selenide,” “CIS/Se,” and “CIS—Se” encompass all possible combinations of CuIn(S,Se)₂, including CuInS₂, CuInSe₂, and CuInSₓSe₂₋ₓ, where 0≦x≦2. Herein, the terms “copper indium gallium sulfide/selenide” and “CIGS/Se” and “GIGS—Se” encompass all possible combinations of Cu(In_{y}Ga_{1-y})(SₓSe₂₋ₓ) where O<y≦I and 0≦x≦2. The terms “CIS,” “CISe,” “CIS/Se,” and “CIGS/Se” further encompass copper indium gallium sulfide/selenide semiconductors with fractional stoichiometries, e.g., Cu_{0.7}In_{1.1}S₂. That is, the stoichiometry of the elements can vary from a strictly 1:1:2 molar ratio for Cu:(In+Ga):(S+Se). Materials designated as CIGS/Se can also contain small amounts of other elements such as sodium. Highly efficient CIGS/Se solar cells are often copper poor, that is the molar ratio of Cu:(In+Ga) is less than one.

As used herein, “coherent domain size” refers to the size of crystalline domains over which a defect-free, coherent structure can exist. The coherency comes from the fact that the three-dimensional ordering is not broken inside of these domains. When the coherent grain size is less than about 100 nm, appreciable broadening of the x-ray diffraction lines will occur. The domain size can be estimated by measuring the full width at half maximum intensity of the diffraction peak.

Herein, the term “metal salts” refers to compositions wherein metal cations and inorganic anions are joined by ionic bonding. Relevant classes of inorganic anions comprise oxides, sulfides, selenides, carbonates, sulfates and halides. Herein, the term “metal complexes” refers to compositions wherein a metal is bonded to a surrounding array of molecules or anions, typically called “ligands” or “complexing agents.” The atom within a ligand that is directly bonded to the metal atom or ion is called the “donor atom” and, herein, often comprises nitrogen, oxygen, selenium, or sulfur.

Herein, ligands are classified according to M. L. H. Green's “Covalent Bond Classification (CBC) Method.” An “X-function ligand” is one which interacts with a metal center via a normal two-electron covalent bond, composed of one electron from the metal and one electron from the X ligand. Simple examples of X-type ligands include alkyls and thiolates. Herein, the term “nitrogen-, oxygen-, carbon-, sulfur-, or selenium-based organic ligands” refers specifically to carbon-containing X-function ligands, wherein the donor atom comprises nitrogen, oxygen, carbon, sulfur, or selenium. Herein, the term “complexes of nitrogen-, oxygen-, carbon-, sulfur-, or selenium-based organic ligands” refers to the metal complexes comprising these ligands. Examples include metal complexes of amidos, alkoxides, acetylacetonates, acetates, carboxylates, hydrocarbyls, O-, N-, S-, Se- or halogen-substituted hydrocarbyls, thiolates, selenolates, thiocarboxylates, selenocarboxylates, dithiocarbamates, and diselenocarbamates.

As defined herein, a “hydrocarbyl group” is a univalent group containing only carbon and hydrogen. Examples of hydrocarbyl groups include unsubstituted alkyls, cycloalkyls, and aryl groups, including alkyl-substituted aryl groups. Suitable hydrocarbyl groups and alkyl groups contain 1 to about 30 carbons, or 1 to 25, 1 to 20, 1 to 15, 1 to 10, 1 to 5, 1 to 4, or 1 to 2 carbons. By “heteroatom-substituted hydrocarbyl” is meant a hydrocarbyl group that contains one or more heteroatoms, wherein the free valence is located on carbon, not on the heteroatom. Examples include hydroxyethyl and carbomethoxyethyl. Suitable heteroatom substituents include O-, N-, S-, Se-, halogen, and tri(hydrocarbyl)silyl. In a substituted hydrocarbyl, all of the hydrogens can be substituted, as in trifluoromethyl. Herein, the term “tri(hydrocarbyl)silyl” encompasses silyl substituents, wherein the substituents on silicon are hydrocarbyls. Herein, by “O-, N-, S-, or Se-based functional groups” is meant univalent groups other than hydrocarbyl and substituted hydrocarbyl that comprise O-, N-, S-, or Se-heteroatoms, wherein the free valence is located on this heteroatom. Examples of O-, N-, S-, and Se-based functional groups include alkoxides, amidos, thiolates, and selenolates.

### Molecular Precursors to CIGS/Se

One aspect of this invention is a molecular precursor to CIGS/Se comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or
a mixture thereof;
provided that:
   if the copper source is copper sulfide or copper selenide, and the indium source is indium sulfide or indium selenide, then the vehicle does not comprise hydrazine.

In some embodiments, the molecular precursor consists essentially of components (i)-(ii) and (iv).

In some embodiments, a gallium source is present. In some embodiments, a gallium source is present and the molecular precursor consists essentially of components (i)-(iv).

In some embodiments, the copper source is selected from the group consisting of copper complexes of nitrogen-, oxygen-, carbon-, sulfur-, or selenium-based organic ligands and mixtures thereof.

In some embodiments, the copper source is selected from the group consisting of copper sulfides, copper selenides, and mixtures thereof.

In some embodiments, the indium source is selected from the group consisting of indium complexes of nitrogen-, oxygen-, carbon-, sulfur-, or selenium-based organic ligands and mixtures thereof.

In some embodiments, the indium source is selected from the group consisting of indium sulfides, indium selenides, and mixtures thereof.

In some embodiments, the copper source is selected from the group consisting of copper complexes of nitrogen-, oxygen-, carbon-, sulfur-, or selenium-based organic ligands and mixtures thereof, and the indium source is selected from the group consisting of indium complexes of nitrogen-, oxygen-, carbon-, sulfur-, or selenium-based organic ligands and mixtures thereof.

In some embodiments, the copper source is selected from the group consisting of copper complexes of nitrogen-, oxygen-, carbon-, sulfur-, or selenium-based organic ligands and mixtures thereof, and the indium source is selected from the group consisting of indium sulfides, indium selenides, and mixtures thereof.

In some embodiments, the copper source is selected from the group consisting of copper sulfides, copper selenides, and mixtures thereof, and the indium source is selected from the group consisting of indium complexes of nitrogen-, oxygen-, carbon-, sulfur-, or selenium-based organic ligands and mixtures thereof.

Chalcogen Compounds.

In some embodiments, the molecular precursor further comprises a chalcogen compound. In some embodiments, the copper source is selected from the group consisting of copper complexes of nitrogen-, oxygen-, carbon-, sulfur-, or selenium-based organic ligands and mixtures thereof, or the indium source is selected from the group consisting of indium complexes of nitrogen-, oxygen-, carbon-, sulfur-, or selenium-based organic ligands and mixtures thereof, and the molecular precursor further comprises a chalcogen compound. In some embodiments, the copper or indium source comprises a nitrogen-, oxygen-, or carbon-based organic ligand, and the molecular precursor further comprises a chalcogen compound. In some embodiments, the copper and indium sources comprise a nitrogen-, oxygen-, or carbon-based organic ligand, and the molecular precursor further comprises a chalcogen compound.

Suitable chalcogen compounds include: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof, with each Z independently selected from the group consisting of: H, NR⁴₄, and SiR⁵₃; wherein each R¹ and R⁵ is independently selected from the group consisting of: hydrocarbyl and O-, N-, S-, Se-, halogen- or tri(hydrocarbyl)silyl-substituted hydrocarbyl; each R² is independently selected from the group consisting of hydrocarbyl, O-, N-, S-, Se-, halogen-, or tri(hydrocarbyl)silyl-substituted hydrocarbyl, and O-, N-, S-, or Se-based functional groups; and each R⁴ is independently selected from the group consisting of hydrogen, O-, N-, S-, Se-, halogen- or tri(hydrocarbyl)silyl-substituted hydrocarbyl, and O-, N-, S-, or Se-based functional groups. In some embodiments, elemental sulfur, elemental selenium, or a mixture of elemental sulfur and selenium is present.

For the chalcogen compounds, suitable R¹S— and R¹Se— of R¹S—Z and R¹Se—Z are selected from the following ligand lists of suitable thiolates and selenolates.

For the chalcogen compounds, suitable R¹S—SR¹ and R¹Se—SeR¹ include: methyl disulfide, 2,2′-dipyridyl disulfide, (2-thienyl) disulfide, (2-hydroxyethyl) disulfide, (2-methyl-3-furyl) disulfide, (6-hydroxy-2-naphthyl) disulfide, ethyl disulfide, methylpropyl disulfide, allyl disulfide, propyl disulfide, isopropyl disulfide, butyl disulfide, sec-butyl disulfide, (4-methoxyphenyl) disulfide, benzyl disulfide, p-tolyl disulfide, phenylacetyl disulfide, tetramethylthiuram disulfide, tetraethylthiuram disulfide, tetrapropylthiuram disulfide, tetrabutylthiuram disulfide, methylxanthic disulfide, ethylxanthic disulfide, i-propylxanthic disulfide, benzyl diselenide, methyl diselenide, ethyl diselenide, phenyl diselenide, and mixtures thereof.

For the chalcogen compounds, suitable R²C(S)S—Z, R²C(Se)Se—Z, R²C(Se)S—Z, R¹C(O)S—Z, and R¹C(O)Se—Z are selected from the ligand lists (below) of suitable thio-, seleno-, and dithiocarboxylates; suitable dithio-, diseleno-, and thioselenocarbamates; and suitable dithioxanthogenates.

Suitable NR⁴₄ include: Et₂NH₂, Et₄N, Et₃NH, EtNH₃, NH₄, Me₂NH₂, Me₄N, Me₃NH, MeNH₃, Pr₂NH₂, Pr₄N, Pr₃NH, PrNH₃, Bu₃NH, Me₂PrNH, (i-Pr)₃NH, and mixtures thereof.

Suitable SiR⁵₃ include: SiMe₃, SiEt₃, SiPr₃, SiBu₃, Si(i-Pr)₃, SiEtMe₂, SiMe₂(i-Pr), Si(t-Bu)Me₂, Si(cyclohexyl)Me₂, and mixtures thereof.

Many of these chalcogen compounds are commercially available or readily synthesized by the addition of an amine, alcohol, or alkyl nucleophile to CS₂ or CSe₂ or CSSe.

Molar Ratios of the Molecular Precursor.

In some embodiments, the molar ratio of Cu:(In+Ga) is about 1 in the molecular precursor. In some embodiments, the molar ratio of Cu:(In+Ga) is less than 1. In some embodiments, the molar ratio of total chalcogen to (Cu+In+Ga) is at least about 1 in the molecular precursor.

As defined herein, sources for the total chalcogen include the metal chalcogenides (e.g., the copper, indium, and gallium sulfides and selenides of the molecular precursor), the sulfur- and selenium-based organic ligands and the optional chalcogen compound of the molecular precursor.

As defined herein, the moles of total chalcogen are determined by multiplying the moles of each metal chalcogenide by the number of equivalents of chalcogen that it contains and then summing these quantities together with the number of moles of any sulfur- or selenium-based organic ligands and optional chalcogen compound. Each sulfur- or selenium-based organic ligand and compound is assumed to contribute just one equivalent of chalcogen in this determination of total chalcogen. This is because not all of the chalcogen atoms contained within each ligand and compound will necessarily be available for incorporation into CIGS/Se; some of the chalcogen atoms from these sources can be incorporated into organic by-products.

The moles of (Cu+In+Ga) are determined by multiplying the moles of each Cu-, or In-, or Ga-containing species by the number of equivalents of Cu, In or Ga that it contains and then summing these quantities. As an example, the molar ratio of total chalcogen to (Cu+In+Ga) for an ink comprising indium(III) acetate, copper(II) dimethyldithiocarbamate (CuDTC), 2-mercaptoethanol (MCE), and sulfur=[2(moles of CuDTC)+(moles of MCE)+(moles of S)]/[(moles of In acetate)+(moles of CuDTC)].

In some embodiments, elemental sulfur, elemental selenium, or a mixture of elemental sulfur and selenium is present in the molecular precursor, and the molar ratio of elemental (S+Se) is about 0.2 to about 5, or about 0.5 to about 2.5, relative to the copper source of the molecular precursor.

Organic Ligands.

In some embodiments, the nitrogen-, oxygen-, carbon-, sulfur- or selenium-based organic ligands are selected from the group consisting of: amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates. Many of these are commercially available or readily synthesized by the addition of an amine, alcohol, or alkyl nucleophile to CS₂ or CSe₂ or CSSe.

Amidos.

Suitable amidos include: bis(trimethylsilyl)amino, dimethylamino, diethylamino, diisopropylamino, N-methyl-t-butylamino, 2-(dimethylamino)-N-methylethylamino, N-methylcyclohexylamino, dicyclohexylamino, N-ethyl-2-methylallylamino, bis(2-methoxyethyl)amino, 2-methylaminomethyl-1,3-dioxolane, pyrrolidino, t-butyl-1-piperazinocarboxylate, N-methylanilino, N-phenylbenzylamino, N-ethyl-o-toluidino, bis(2,2,2-trifluoromethyl)amino, N-t-butyltrimethylsilylamino, and mixtures thereof. Some ligands can chelate the metal center, and, in some cases, comprise more than one type of donor atom, e.g., the dianion of N-benzyl-2-aminoethanol is a suitable ligand comprising both amino and alkoxide groups.

Alkoxides. Suitable alkoxides include: methoxide, ethoxide, n-propoxide, i-propoxide, n-butoxide, t-butoxide, neopentoxide, ethylene glycol dialkoxide, 1-methylcyclopentoxide, 2-fluoroethoxide, 2,2,2-trifluoroethoxide, 2-ethoxyethoxide, 2-methoxyethoxide, 3-methoxy-1-butoxide, methoxyethoxyethoxide, 3,3-diethoxy-1-propoxide, 2-dimethylaminoethoxide, 2-diethylaminoethoxide, 3-dimethylamino-1-propoxide, 3-diethylamino-1-propoxide, 1-dimethylamino-2-propoxide, 1-diethylamino-2-propoxide, 2-(1-pyrrolidinyl)ethoxide, 1-ethyl-3-pyrrolidinoxide, 3-acetyl-1-propoxide, 4-methoxyphenoxide, 4-chlorophenoxide, 4-t-butylphenoxide, 4-cyclopentylphenoxide, 4-ethylphenoxide, 3,5-bis(trifluoromethyl)phenoxide, 3-chloro-5-methoxyphenoxide, 3,5-dimethoxyphenoxide, 2,4,6-trimethylphenoxide, 3,4,5-trimethylphenoxide, 3,4,5-trimethoxyphenoxide, 4-t-butyl-catecholate(2-), 4-propanoylphenoxide, 4-(ethoxycarbonyl)phenoxide, 3-(methylthio)-1-propoxide, 2-(ethylthio)-1-ethoxide, 2-(methylthio)ethoxide, 4-(methylthio)-1-butoxide, 3-(methylthio)-1-hexoxide, 2-methoxybenzylalkoxide, 2-(trimethylsilyl)ethoxide, (trimethylsilyl)methoxide, 1-(trimethylsilyl)ethoxide, 3-(trimethylsilyl)propoxide, 3-methylthio-1-propoxide, and mixtures thereof.

Acetylacetonates.

Herein, the term acetylacetonate refers to the anion of 1,3-dicarbonyl compounds, A¹C(O)CH(A²)C(O)A¹, wherein each A¹ is independently selected from hydrocarbyl, substituted hydrocarbyl, and O-, S-, or N-based functional groups and each A² is independently selected from hydrocarbyl, substituted hydrocarbyl, halogen, and O-, S-, or N-based functional groups. Suitable acetylacetonates include: 2,4-pentanedionate, 3-methyl-2,4-pentanedionate, 3-ethyl-2,4-pentanedionate, 3-chloro-2,4-pentanedionate, 1,1,1-trifluoro-2,4-pentanedionate, 1,1,1,5,5,5-hexafluoro-2,4-pentanedionate, 1,1,1,5,5,6,6,6,-octafluoro-2,4-hexanedionate, ethyl 4,4,4-trifluoroacetoacetate, 2-methoxyethylacetoacetate, methylacetoacetate, ethylacetoacetate, t-butylacetoacetate, 1-phenyl-1,3-butanedionate, 2,2,6,6-tetramethyl-3,5-heptanedionate, allyloxyethoxytrifluoroacetoacetate, 4,4,4-trifluoro-1-phenyl-1,3-butanedionate, 1,3-diphenyl-1,3-propanedionate, 6,6,7,7,8,8,8-heptafluoro-2,2-dimethyl-3,5-octanedionate, and mixtures thereof.

Carboxylates.

Suitable carboxylates include: formate, acetate, trifluoroacetate, propionate, butyrates, hexanoate, octanoate, decanoate, stearate, isobutyrate, t-butylacetate, heptafluorobutyrate, methoxyacetate, ethoxyacetate, methoxypropionate, 2-ethyl hexanoate, 2-(2-methoxyethoxy)acetate, 2-[2-(2-methoxyethoxy)ethoxy]acetate, (methylthio)acetate, tetrahydro-2-furoate, 4-acetyl butyrate, phenylacetate, 3-methoxyphenylacetate, (trimethylsilyl)acetate, 3-(trimethylsilyl)propionate, maleate, benzoate, acetylenedicarboxylate, and mixtures thereof.

Hydrocarbyls.

Suitable hydrocarbyls include: methyl, ethyl, n-propyl, i-propyl, n-butyl, i-butyl, sec-butyl, t-butyl, n-pentyl, n-hexyl, n-heptyl, n-octyl, neopentyl, 3-methylbutyl, phenyl, benzyl, 4-t-butylbenzyl, 4-t-butylphenyl, p-tolyl, 2-methyl-2-phenylpropyl, 2-mesityl, 2-phenylethyl, 2-ethylhexyl, 2-methyl-2-phenylpropyl, 3,7-dimethyloctyl, allyl, vinyl, cyclopentyl, cyclohexyl, and mixtures thereof.

Substituted Hydrocarbyls.

Suitable O-, N-, S-, halogen- or tri(hydrocarbyl)silyl-substituted hydrocarbyls include: 2-methoxyethyl, 2-ethoxyethyl, 4-methoxyphenyl, 2-methoxybenzyl, 3-methoxy-1-butyl, 1,3-dioxan-2-ylethyl, 3-trifluoromethoxyphenyl, 3,4-(methylenedioxy)phenyl, 2,4-dimethoxyphenyl, 2,5-dimethoxyphenyl, 3,4-dimethoxyphenyl, 2-methoxybenzyl, 3-methoxybenzyl, 4-methoxybenzyl, 3,5-dimethoxyphenyl, 3,5-dimethyl-4-methoxyphenyl, 3,4,5-trimethoxyphenyl, 4-methoxyphenethyl, 3,5-dimethoxybenzyl, 4-(2-tetrahydro-2H-pyranoxy)phenyl, 4-phenoxyphenyl, 2-benzyloxyphenyl, 3-benzyloxyphenyl, 4-benzyloxyphenyl, 3-fluoro-4-methoxyphenyl, 5-fluoro-2-methoxyphenyl, 2-ethoxyethenyl, 1-ethoxyvinyl, 3-methyl-2-butenyl, 2-furyl, carbomethoxyethyl, 3-dimethylamino-1-propyl, 3-diethylamino-1-propyl, 3-[bis(trimethylsilyl)amino]phenyl, 4-(N,N-dimethyl)aniline, [2-(1-pyrrolidinylmethyl)phenyl], [3-(1-pyrrolidinylmethyl)phenyl], [4-(1-pyrrolidinylmethyl)phenyl], [2-(4-morpholinylmethyl)phenyl], [3-(4-morpholinylmethyl)phenyl], [4-(4-morpholinylmethyl)phenyl], (4-(1-piperidinylmethyl)phenyl), (2-(1-piperidinylmethyl)phenyl), (3-(1-piperidinylmethyl)phenyl), 3-(1,4-dioxa-8-azaspiro[4,5]dec-8-ylmethyl)phenyl, 1-methyl-2-pyrrolyl, 2-fluoro-3-pyridyl, 6-methoxy-2-pyrimidyl, 3-pyridyl, 5-bromo-2-pyridyl, 1-methyl-5-imidazolyl, 2-chloro-5-pyrimidyl, 2,6-dichloro-3-pyrazinyl, 2-oxazolyl, 5-pyrimidyl, 2-pyridyl, 2-(ethylthio)ethyl, 2-(methylthio)ethyl, 4-(methylthio)butyl, 3-(methylthio)-1-hexyl, 4-thioanisole, 4-bromo-2-thiazolyl, 2-thiophenyl, chloromethyl, 4-fluorophenyl, 3-fluorophenyl, 4-chlorophenyl, 3-chlorophenyl, 4-fluoro-3-methylphenyl, 4-fluoro-2-methylphenyl, 4-fluoro-3-methylphenyl, 5-fluoro-2-methylphenyl, 3-fluoro-2-methylphenyl, 4-chloro-2-methylphenyl, 3-fluoro-4-methylphenyl, 3,5-bis(trifluoromethyl)-phenyl, 3,4,5-trifluorophenyl, 3-chloro-4-fluorophenyl, 3-chloro-5-fluorophenyl, 4-chloro-3-fluorophenyl, 3,4-dichlorophenyl, 3,5-dichlorophenyl, 3,4-difluorophenyl, 3,5-difluorophenyl, 2-bromobenzyl, 3-bromobenzyl, 4-fluorobenzyl, perfluoroethyl, 2-(trimethylsilyl)ethyl, (trimethylsilyl)methyl, 3-(trimethylsilyl)propyl, and mixtures thereof.

Thio- and Selenolates. Suitable thiolates and selenolates include: 1-thioglycerol, phenylthio, ethylthio, methylthio, n-propylthio, i-propylthio, n-butylthio, i-butylthio, t-butylthio, n-pentylthio, n-hexylthio, n-heptylthio, n-octylthio, n-nonylthio, n-decylthio, n-dodecylthio, 2-methoxyethylthio, 2-ethoxyethylthio, 1,2-ethanedithiolate, 2-pyridinethiolate, 3,5-bis(trifluoromethyl)benzenethiolate, toluene-3,4-dithiolate, 1,2-benzenedithiolate, 2-dimethylaminoethanethiolate, 2-diethylaminoethanethiolate, 2-propene-1-thiolate, 2-hydroxythiolate, 3-hydroxythiolate, methyl-3-mercaptopropionate anion, cyclopentanethiolate, 2-(2-methoxyethoxy)ethanethiolate, 2-(trimethylsilyl)ethanethiolate, pentafluorophenylthiolate, 3,5-dichlorobenzenethiolate, phenylthiolate, cyclohexanethiolate, 4-chlorobenzenemethanethiolate, 4-fluorobenzenemethanethiolate, 2-methoxybenzenethiolate, 4-methoxybenzenethiolate, benzylthiolate, 3-methylbenzylthiolate, 3-ethoxybenzenethiolate, 2,5-dimethoxybenzenethiolate, 2-phenylethanethiolate, 4-t-butylbenzenethiolate, 4-t-butylbenzylthiolate, phenylselenolate, methylselenolate, ethylselenolate, n-propylselenolate, i-propylselenolate, n-butylselenolate, i-butylselenolate, t-butylselenolate, pentylselenolate, hexylselenolate, octylselenolate, benzylselenolate, and mixtures thereof.

Carboxylates, Carbamates, and Xanthogenates.

Suitable thio-, seleno-, and dithiocarboxylates include: thioacetate, thiobenzoate, selenobenzoate, dithiobenzoate, and mixtures thereof. Suitable dithio-, diseleno-, and thioselenocarbamates include: dimethyldithiocarbamate, diethyldithiocarbamate, dipropyldithiocarbamate, dibutyldithiocarbamate, bis(hydroxyethyl)dithiocarbamate, dibenzyldithiocarbamate, dimethyldiselenocarbamate, diethyldiselenocarbamate, dipropyldiselenocarbamate, dibutyldiselenocarbamate, dibenzyldiselenocarbamate, and mixtures thereof. Suitable dithioxanthogenates include: methylxanthogenate, ethylxanthogenate, i-propylxanthogenate, and mixtures thereof.

Vehicle.

The molecular precursor comprises a vehicle, comprising a liquid chalcogen compound, a solvent, or a mixture thereof. In some embodiments, the vehicle comprises about 99 to about 1 wt %, 95 to about 5 wt %, 90 to 10 wt %, 80 to 20 wt %, 70 to 30 wt %, or 60 to 40 wt % of the molecular precursor, based upon the total weight of the molecular precursor. In some embodiments, the vehicle comprises at least about 2 wt %, 5 wt %, 10 wt %, 20 wt %, 30 wt %, 40 wt %, 50 wt %, 60 wt %, 70 wt %, 80 wt %, 90 wt %, or 95 wt % of the molecular precursor, based upon the total weight of the molecular precursor. In some embodiments, the vehicle comprises a liquid chalcogen compound.

Solvents. In some embodiments, the vehicle comprises a solvent. In some embodiments, the boiling point of the solvent is greater than about 100° C., 110° C., 120° C., 130° C., 140° C., 150° C., 160° C., 170° C., 180° C. or 190° C. at atmospheric pressure. In some embodiments, the process is conducted at atmospheric pressure. Suitable solvents include: aromatics, heteroaromatics, nitriles, amides, alcohols, pyrrolidinones, amines, and mixtures thereof. Suitable heteroaromatics include pyridine and substituted pyridines. Suitable amines include compounds of the form R⁶NH₂, wherein each R⁶ is independently selected from the group consisting of: O-, N-, S-, or Se-substituted hydrocarbyl. In some embodiments, the solvent comprises an amino-substituted pyridine.

Aromatics.

Suitable aromatic solvents include: benzene, toluene, ethylbenzene, chlorobenzene, o-xylene, m-xylene, p-xylene, mesitylene, i-propylbenzene, 1-chlorobenzene, 2-chlorotoluene, 3-chlorotoluene, 4-chlorotoluene, t-butylbenzene, n-butylbenzene, i-butylbenzene, s-butylbenzene, 1,2-dichlorobenzene, 1,3-dichlorobenzene, 1,4-dichlorobenzene, 1,3-diisopropylbenzene, 1,4-diisopropylbenzene, 1,2-difluorobenzene, 1,2,4-trichlorobenzene, 3-methylanisole, 3-chloroanisole, 3-phenoxytoluene, diphenylether, and mixtures thereof.

Heteroaromatics.

Suitable heteroaromatic solvents include: pyridine, 2-picoline, 3-picoline, 3,5-lutidine, 4-t-butylpyridine, 2-aminopyridine, 3-aminopyridine, diethylnicotinamide, 3-cyanopyridine, 3-fluoropyridine, 3-chloropyridine, 2,3-dichloropyridine, 2,5-dichloropyridine, 5,6,7,8-tetrahydroisoquinoline, 6-chloro-2-picoline, 2-methoxypyridine, 3-(aminomethyl)pyridine, 2-amino-3-picoline, 2-amino-6-picoline, 2-amino-2-chloropyridine, 2,3-diaminopyridine, 3,4-diaminopyridine, 2-(methylamino)pyridine, 2-dimethylaminopyridine, 2-(aminomethyl)pyridine, 2-(2-aminoethyl)pyridine, 2-methoxypyridine, 2-butoxypyridine, and mixtures thereof.

Nitriles.

Suitable nitrile solvents include: acetonitrile, 3-ethoxypropionitrile, 2,2-diethoxypropionitrile, 3,3-diethoxypropionitrile, diethoxyacetonitrile, 3,3-dimethoxypropionitrile, 3-cyanopropionaldehyde dimethylacetal, dimethylcyanamide, diethylcyanamide, diisopropylcyanamide, 1-pyrrolidinecarbonitrile, 1-piperidinecarbonitrile, 4-morpholinecarbonitrile, methylaminoacetonitrile, butylaminoacetonitrile, dimethylaminoacetonitrile, diethylaminoacetonitrile, N-methyl-beta-alaninenitrile, 3,3′-iminopropionitrile, 3-(dimethylamino)propionitrile, 1-piperidinepropionitrile, 1-pyrrolidinebutyronitrile, propionitrile, butyronitrile, valeronitrile, isovaleronitrile, 3-methoxypropionitrile, 3-cyanopyridine, 4-amino-2-chlorobenzonitrile, 4-acetylbenzonitrile, and mixtures thereof.

Amides.

Suitable amide solvents include: N,N-diethylnicotinamide, N-methylnicotinamide, N,N-dimethylformamide, N,N-diethylformamide, N,N-diisopropylformamide, N,N-dibutylformamide, N,N-dimethylacetamide, N,N-diethylacetamide, N,N-diisopropylacetamide, N,N-dimethylpropionamide, N,N-diethylpropionamide, N,N,2-trimethylpropionamide, acetamide, propionamide, isobutyramide, trimethylacetamide, nipecotamide, N,N-diethylnipecotamide, and mixtures thereof.

Alcohols.

Suitable alcohol solvents include: methoxyethoxyethanol, methanol, ethanol, isopropanol, 1-butanol, 2-pentanol, 2-hexanol, 2-octanol, 2-nonanol, 2-decanol, 2-dodecanol, ethylene glycol, 1,3-propanediol, 2,3-butanediol, 1,5-pentanediol, 1,6-hexanediol, 1,7-heptanediol, 1,8-octanediol, cyclopentanol, cyclohexanol, cyclopentanemethanol, 3-cyclopentyl-1-propanol, 1-methylcyclopentanol, 3-methylcyclopentanol, 1,3-cyclopentanediol, 2-cyclohexylethanol, 1-cyclohexylethanol, 2,3-dimethylcyclohexanol, 1,3-cyclohexanediol, 1,4-cyclohexanediol, cycloheptanol, cyclooctanol, 1,5-decalindiol, 2,2-dichloroethanol, 2,2,2-trifluoroethanol, 2-methoxyethanol, 2-ethoxyethanol, 2-propoxyethanol, 2-butoxyethanol, 3-ethoxy-1-propanol, propyleneglycol propyl ether, 3-methoxy-1-butanol, 3-methoxy-3-methyl-1-butanol, 3-ethoxy-1,2-propanediol, di(ethyleneglycol) ethylether, diethylene glycol, 2,4-dimethylphenol, and mixtures thereof.

Pyrrolidinones.

Suitable pyrrolidinone solvents include: N-methyl-2-pyrrolidinone, 5-methyl-2-pyrrolidinone, 3-methyl-2-pyrrolidinone, 2-pyrrolidinone, 1,5-dimethyl-2-pyrrolidinone, 1-ethyl-2-pyrrolidinone, 1-(2-hydroxyethyl)-2-pyrrolidinone, 5-methoxy-2-pyrrolidinone, 1-(3-aminopropyl)-2-pyrrolidinone, and mixtures thereof.

Amines. Suitable amine solvents include: butylamine, hexylamine, octylamine, 3-methoxypropylamine, 2-methylbutylamine, isoamylamine, 1,2-dimethylpropylamine, hydrazine, ethylenediamine, 1,3-diaminopropane, 1,2-diaminopropane, 1,2-diamino-2-methylpropane, 1,3-diaminopentane, 1,1-dimethylhydrazine, N-ethylmethylamine, diethylamine, N-methylpropylamine, diisopropylamine, dibutylamine, triethylamine, N-methylethylenediamine, N-ethylethylenediamine, N-propylethylenediamine, N-isopropylethylenediamine, N,N′-dimethylethylenediamine, N,N-dimethylethylenediamine, N,N′-diethylethylenediamine, N,N-diethylethylenediamine, N,N-diisopropylethylenediamine, N,N-dibutylethylenediamine, N,N,N′-trimethylethylenediamine, 3-dimethylaminopropylamine, 3-diethylaminopropylamine, diethylenetriamine, cyclohexylamine, bis(2-methoxyethyl)amine, aminoacetaldehyde diethyl acetal, methylaminoacetaldehyde dimethyl acetal, N,N-dimethylacetamide dimethyl acetal, dimethylaminoacetaldehyde diethyl acetal, diethylaminoacetaldehyde diethyl acetal, 4-aminobutyraldehyde diethyl acetal, 2-methylaminomethyl-1,3-dioxolane, ethanolamine, 3-amino-1-propanol, 2-hydroxyethylhydrazine, N,N-diethylhydroxylamine, 4-amino-1-butanol, 2-(2-aminoethoxy)ethanol, 2-(methylamino)ethanol, 2-(ethylamino)ethanol, 2-(propylamino)ethanol, diethanolamine, diisopropanolamine, N,N-dimethylethanolamine, N,N-diethylethanolamine, 2-(dibutylamino)ethanol, 3-dimethylamino-1-propanol, 3-diethylamino-1-propanol, 1-dimethylamino-2-propanol, 1-diethylamino-2-propanol, N-methyldiethanolamine, N-ethyldiethanolamine, 3-amino-1,2-propanediol, and mixtures thereof.

Molecular Precursor Preparation.

Preparing the molecular precursor typically comprises mixing the components (i)-(iv) by any conventional method. If one or more of the chalcogen sources is a liquid at room temperature or at the processing temperatures, the use of a separate solvent is optional. Otherwise, a solvent is used. In some embodiments, the molecular precursor is a solution; in other embodiments, the molecular precursor is a suspension or dispersion. Typically, the preparation is conducted under an inert atmosphere, taking precautions to protect the reaction mixtures from air and light.

In some embodiments, the molecular precursor is initially prepared at low temperatures and/or with slow additions, e.g., when larger amounts of reagents and/or low boiling point and/or highly reactive reagents such as CS₂ are utilized. In such cases, the ink is typically stirred at room temperature prior to heat-processing. In some embodiments, the molecular precursor is prepared at about 20-100° C., e.g., when smaller amounts of reagents are used, when the reagents are solids or have high boiling points and/or when one or more of the solvents is a solid at room temperature, e.g., 2-aminopyridine or 3-aminopyridine. In some embodiments, all of the ink components are added together at room temperature, e.g., when smaller amounts of reagents are used. In some embodiments, elemental chalcogen is added last, following the mixing of all the other components for about half an hour at room temperature. In some embodiments, the components are added consecutively. For example, the indium source can be added slowly with mixing to a suspension of the copper source in the vehicle, followed by the addition of the chalcogen source(s).

Heat-Processing of the Molecular Precursor.

In some embodiments, the molecular precursor is heat-processed at a temperature of greater than about 90° C., 100° C., 110° C., 120° C., 130° C., 140° C., 150 C°, 160° C., 170° C., 180° C. or, 190° C. before coating on the substrate. Suitable heating methods include conventional heating and microwave heating. In some embodiments, it has been found that this heat-processing step aids the formation of CIGS/Se. This optional heat-processing step is typically carried out under an inert atmosphere. The molecular precursor produced at this stage can be stored for extended periods (e.g., months) without any noticeable decrease in efficacy.

Additives.

In various embodiments, the molecular precursor can further comprise one or more additives. These additives are typically added to the molecular precursor at room temperature, following the mixing and optional heat processing of components (i)-(iv) of the molecular precursor. These additives are typically mixed with the molecular precursor under an inert atmosphere using conventional methods.

Suitable additives include dispersants, surfactants, polymers, binders, ligands, capping agents, defoamers, thickening agents, corrosion inhibitors, plasticizers, thixotropic agents, viscosity modifiers, and dopants.

In some embodiments, additives are selected from the group consisting of: capping agents, dopants, polymers, and surfactants. In some embodiments, the ink comprises up to about 10 wt %, 7.5 wt %, 5 wt %, 2.5 wt % or 1 wt % additives, based upon the total weight of the ink. Capping Agents. Suitable capping agents include:

(a) Organic molecules that contain functional groups such as N-, O-, S-, Se- or P-based functional groups;

(b) Lewis bases;

(c) Amines, thiols, selenols, phosphine oxides, phosphines, phosphinic acids, pyrrolidones, pyridines, carboxylates, phosphates, heteroaromatics, peptides, and alcohols;

(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol;

(e) Inorganic chalcogenides, including metal chalcogenides, and zintl ions; (f) S²⁻, Se²⁻, Se₂²⁻, Se₃²⁻, Se₄²⁻, Se₆²⁻, Te₂²⁻, Te₃²⁻, Te₄²⁻, In₂Se₄²⁻, and In₂Te₄²⁻, wherein the positively charged counterions can be alkali metal ions, ammonium, hydrazinium, or tetraalkylammonium;

(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. These capping agents can be degraded by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles;

(h) Molecular precursor complexes to copper chalcogenides, indium chalcogenides, and gallium chalcogenides. Ligands for these molecular precursor complexes include: thio groups, seleno groups, thiolates, selenolates, and thermally degradable ligands, as described above;

(i) Molecular precursor complexes to CuS/Se, Cu₂S/Se, InS/Se, In₂(S/Se)₃, GaS/Se; and

(j) Short-chain carboxylic acids, such as formic, acetic, or oxalic acids.

The Lewis base can be chosen such that it has a boiling temperature at ambient pressure that is greater than or equal to about 200° C., 150° C., 120° C., or 100° C., and/or can be selected from the group consisting of: organic amines, phosphine oxides, phosphines, thiols, and mixtures thereof. In some embodiments, the capping agent comprises a surfactant or a dispersant.

Volatile Capping Agents.

Suitable capping agents include volatile capping agents. A capping agent is considered volatile if, instead of decomposing and introducing impurities, it evaporates during film deposition, drying or annealing. Volatile capping agents include those having a boiling point less than about 200° C., 150° C., 120° C., or 100° C. at ambient pressure. Suitable volatile capping agents include: ammonia, methyl amine, ethyl amine, propylamine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

Dopants.

Suitable dopants include sodium and alkali-containing compounds. In some embodiments, the alkali-containing compounds are selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates. Other suitable dopants include antimony chalcogenides selected from the group consisting of antimony sulfide and antimony selenide.

Polymers and Surfactants.

Suitable polymeric additives include vinylpyrrolidone-vinylacetate copolymers and (meth)acrylate copolymers, including PVP/VA E-535 (International Specialty Products), and Elvacite® 2028 binder and Elvacite® 2008 binder (Lucite International, Inc.). In some embodiments, polymers can function as binders or dispersants.

Suitable surfactants comprise siloxy-, fluoryl-, alkyl-, alkynyl-, and ammonium-substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants can function as coating aids, capping agents, or dispersants.

In some embodiments, the molecular precursor comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates including, for example, Novomer PPC (Novomer, Inc.); homo- and co-polymers of poly[3-hydroxybutyric acid];
homo- and co-polymers of polymethacrylates; and mixtures thereof. A suitable low-boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxyl acetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

Mixtures of Molecular Precursors.

In some embodiments two or more molecular precursors are prepared separately, with each molecular precursor comprising a complete set of reagents, e.g., each molecular precursor comprises at least a copper source, an indium source and a vehicle. The two or more molecular precursors can then be combined following mixing or following heat-processing. This method is especially useful for controlling stoichiometry and obtaining CIGS/Se of high purity, as prior to combining, separate films from each molecular precursor can be coated, annealed, and analyzed by XRD. The XRD results can then guide the selection of the type and amount of each molecular precursor to be combined. For example, a molecular precursor yielding an annealed film of CIGS/Se with traces of copper sulfide can be combined with a molecular precursor yielding an annealed film of CIGS/Se with traces of indium sulfide, to form a molecular precursor that yields an annealed film comprising only CIGS/Se, as determined by XRD. In some embodiments, an ink comprising a complete set of reagents is combined with ink(s) comprising a partial set of reagents. As an example, an ink containing only an indium source can be added in varying amounts to an ink comprising a complete set of reagents, and the stoichiometry can be optimized based upon the resulting device performances of annealed films of the mixtures.

### Coated Substrate

Another aspect of this invention is a process comprising disposing a molecular precursor to CIGS/Se onto a substrate to form a coated substrate, wherein molecular precursor comprises:

i) a copper source selected from the group consisting of copper complexes of nitrogen-, oxygen-, carbon-, sulfur-, or selenium-based organic ligands, copper sulfides, copper selenides, and mixtures thereof;

ii) an indium source selected from the group consisting of indium complexes of nitrogen-, oxygen-, carbon-, sulfur-, or selenium-based organic ligands, indium sulfides, indium selenides, and mixtures thereof; iii) optionally, a gallium source selected from the group consisting of gallium complexes of nitrogen-, oxygen-, carbon-, sulfur-, or selenium-based organic ligands, gallium sulfides, gallium selenides, and mixtures thereof; and

iv) a vehicle, comprising a liquid chalcogen compound, a solvent, or a mixture thereof;

provided that if the copper source is copper sulfide or copper selenide, and the indium source is indium sulfide or indium selenide, then the vehicle does not comprise hydrazine.

Descriptions and preferences regarding the molecular precursor its components are the same as described above for the molecular precursor composition.

Another aspect of this invention is a coated substrate comprising:

A) a substrate; and
B) at least one layer disposed on the substrate comprising a molecular precursor to CIGS/Se comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof;

wherein at least one of the copper or indium sources comprises complexes of nitrogen-, oxygen-, carbon-, sulfur-, or selenium-based organic ligands.

In some embodiments, the coated substrate further comprises one or more additional layers.

In some embodiments, the copper source is selected from the group consisting of copper complexes of nitrogen-, oxygen-, carbon-, sulfur-, or selenium-based organic ligands and mixtures thereof.

In some embodiments, the copper source is selected from the group consisting of copper sulfides, copper selenides, and mixtures thereof.

In some embodiments, the indium source is selected from the group consisting of indium complexes of nitrogen-, oxygen-, carbon-, sulfur-, or selenium-based organic ligands and mixtures thereof.

In some embodiments, the indium source is selected from the group consisting of indium sulfides, indium selenides, and mixtures thereof.

In some embodiments, the copper source is selected from the group consisting of copper complexes of nitrogen-, oxygen-, carbon-, sulfur-, or selenium-based organic ligands and mixtures thereof, and the indium source is selected from the group consisting of indium complexes of nitrogen-, oxygen-, carbon-, sulfur-, or selenium-based organic ligands and mixtures thereof.

In some embodiments, the copper source is selected from the group consisting of copper complexes of nitrogen-, oxygen-, carbon-, sulfur-, or selenium-based organic ligands and mixtures thereof, and the indium source is selected from the group consisting of indium sulfides, indium selenides, and mixtures thereof.

In some embodiments, the copper source is selected from the group consisting of copper sulfides, copper selenides, and mixtures thereof, and the indium source is selected from the group consisting of indium complexes of nitrogen-, oxygen-, carbon-, sulfur-, or selenium-based organic ligands and mixtures thereof.

In some embodiments, the molecular precursor consists essentially of components (i)-(ii). In some embodiments, the gallium source is present and the molecular precursor consists essentially of components (i)-(iii).

In some embodiments, the molecular precursor further comprises a chalcogen compound. In some embodiments, the copper source is selected from the group consisting of copper complexes of nitrogen-, oxygen-, carbon-, sulfur-, and selenium-based organic ligands and mixtures thereof, or the indium source is selected from the group consisting of indium complexes of nitrogen-, oxygen-, carbon-, sulfur-, and selenium-based organic ligands and mixtures thereof, and the molecular precursor further comprises a chalcogen compound. In some embodiments, the copper or indium source comprises a nitrogen-, oxygen-, or carbon-based organic ligand, and the molecular precursor further comprises a chalcogen compound. In some embodiments, the copper and indium sources comprise a nitrogen-, oxygen-, or carbon-based organic ligand, and the molecular precursor further comprises a chalcogen compound.

In some embodiments, the molecular further comprises an additive.

In some embodiments, the molar ratio of Cu:In in the at least one layer is about 1. In some embodiments, the gallium source is present in the molecular precursor and the molar ratio of Cu:(In+Ga) in the at least one layer is about 1. In some embodiments, the molar ratio of Cu:In in the at least one layer is less than 1. In some embodiments, the gallium source is present in the molecular precursor and the molar ratio of Cu:(In+Ga) in the at least one layer is less than 1. In some embodiments, the molar ratio of total chalcogen to (Cu+In) in the at least one layer is at least about 1. In some embodiments, the gallium source is present in the molecular precursor and the molar ratio of total chalcogen to (Cu+In+Ga) in the at least one layer is at least about 1.

Descriptions and preferences regarding molecular precursor components (i)-(iii), chalcogen compounds, additives, and molar ratios are the same as described above for the molecular precursor composition.

Substrate.

The substrate onto which the ink is disposed can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller-coating, slot-die coating, draw-down coating, ink-jet printing, contact printing, gravure printing, flexographic printing, and screen printing. The coating can be dried by evaporation, by applying vacuum, by heating, by blowing, or by combinations thereof. In some embodiments, the substrate and disposed ink are heated at a temperature from 80-350° C., 100-300° C., 120-250° C., 150-190° C., or 120-170° C. to remove at least a portion of the solvent, if present, by-products, and volatile capping agents. The drying step can be a separate, distinct step, or can occur as the substrate and precursor ink are heated in an annealing step.

Annealing. In some embodiments, the coated substrate is heated at about 100-800° C., 200-800° C., 250-800° C., 300-800° C., 350-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high-energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen to (Cu+In+Ga) in the coating is greater than about 1. If the molar ratio of total chalcogen to (Cu+In+Ga) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above, or vice versa. In some embodiments, the annealing is conducted with slow heating and/or cooling steps, e.g., temperature ramps and declines of less than about 15° C./min, 10° C./min, 5° C./min, 2° C./min, or 1° C./min. In other embodiments, the annealing is conducted with rapid heating and/or cooling steps, e.g., temperature ramps and declines of greater than about 15° C. per min, 20° C. per min, 30° C. per min, 45° C. per min, or 60° C. per min.

Additional Layers.

In some embodiments, the coated substrate further comprises one or more additional layers. These one or more layers can be of the same composition as the at least one layer or can differ in composition. In some embodiments, particularly suitable additional layers comprise CIGS/Se precursors selected from the group consisting of: CIGS/Se molecular precursors, CIGS/Se particles, elemental Cu-, In- or Ga-containing particles; binary or ternary Cu-, In- or Ga-containing chalcogenide particles; and mixtures thereof. In some embodiments, the one or more additional layers are coated on top of the at least one layer. In some embodiments, the one or more additional layers are coated prior to coating the at least one layer. In some embodiments, the additional layers are coated both prior to and subsequent to the coating of the at least one layer.

In some embodiments, a soft-bake step and/or annealing step occurs between coating the at least one layer and the one or more additional layers.

CIGS/Se Composition.

An annealed film comprising CIGS/Se is produced by the above annealing processes. In some embodiments, the coherent domain size of the CIGS/Se film is greater than about 30 nm, 40 nm, 50 nm, 60 nm, 70 nm, 80 nm, 90 nm, or 100 nm, as determined by XRD. In some embodiments, the molar ratio of Cu:In or Cu:(In+Ga) in the film is about 1. In some embodiments, the molar ratio of Cu:In or Cu:(In+Ga) in the film is less than 1.

Coating and Film Thickness. By varying the ink concentration and/or coating technique and temperature, layers of varying thickness can be coated in a single coating step. In some embodiments, the coating thickness can be increased by repeating the coating and drying steps. Annealing steps can also be carried out between the coating of multiple layers. These multiple coatings can be conducted with the same ink or with different inks. As described above, wherein two or more inks are mixed, the coating of multiple layers with different inks can be used to fine-tune stoichiometry and purity of the CIGS/Se films. It can also be used to tune the absorption of the film, e.g., by creating films with gradient CIGS/Se compositions.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun to wash out the organics. Examples of useful solvents for removing organics in the coatings include alcohols, e.g., methanol or ethanol, and hydrocarbons, e.g., toluene. As another example, dip-coating the substrate into the ink can be alternated with dip-coating the coated substrate into a solvent bath to remove impurities and organic compounds. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification, along with lower levels of carbon-based impurities in the film, particularly if and when it is later annealed. Alternatively, binary sulfides and other impurities can be removed by etching the annealed film using standard techniques for CIGS/Se films.

### Preparation of Devices, Including Thin-Film Photovoltaic Cells

Another aspect of this invention is a process for preparing a photovoltaic cell comprising a film comprising CIGS/Se. Various embodiments of the film are the same as described above. In some embodiments, the film is the absorber or buffer layer of a photovoltaic cell.

Various electrical elements can be formed, at least in part, by the use of the molecular precursors to CIGS/Se and processes described herein. One aspect of this invention provides a process for making an electronic device and comprises depositing one or more layers in layered sequence onto the annealed film of the substrate. The layers can be selected from the group consisting of conductors, semiconductors, and insulators.

Another aspect of this invention provides a process for manufacturing thin-film photovoltaic cells comprising CIGS/Se A typical photovoltaic cell includes a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CIGS/Se film in layered sequence.

In one embodiment, the process provides a photovoltaic device and comprises depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CIGS/Se film. In some embodiments, construction and materials for these layers are analogous to those of known CIGS/Se photovoltaic cells. Suitable substrate materials for the photovoltaic cell substrate are as described above.

### INDUSTRIAL UTILITY

Advantages of the inks of the present invention are numerous: 1. Molecular precursors to CIGS/Se can be prepared that form stable dispersions that can be stored for long periods without settling or agglomeration, while keeping the amount of dispersing agent in the ink at a minimum. 2. The overall ratios of copper, indium, gallium, and chalcogenide in the molecular precursor, as well as the sulfur/selenium ratio, can be easily varied to achieve optimum performance of the photovoltaic cell. 3. The use of molecular precursors enables low annealing temperatures and dense film packing. 4. The molecular precursor can be prepared and deposited using a small number of operations and scalable, inexpensive processes. 5. Films of thickness suitable for thin film photovoltaic devices can be deposited in one coating operation. 6. Coatings derived from the molecular precursor can be annealed at atmospheric pressure. Moreover, for certain molecular precursor compositions, only an inert atmosphere is required. For other ink compositions, the use of H₂S or H₂Se is not required to form CIGS/Se, since sulfurization or selenization can be achieved with sulfur or selenium vapor.

### EXAMPLES

### General

Materials.

All reagents were purchased from Aldrich (Milwaukee, Wis.), Alfa Aesar (Ward Hill, M A), TCI (Portland, Oreg.), or Gelest (Morrisville, Pa.). Solid reagents were used without further purification. Liquid reagents that were not packaged under an inert atmosphere were degassed by bubbling argon through the liquid for 1 hr. Anhydrous solvents were used for the preparation of all formulations and for all cleaning procedures carried out within the drybox. Solvents were either purchased as anhydrous from Aldrich or Alfa Aesar, or purified by standard methods (e.g., Pangborn, A. G., et al. Organometallics, 1996, 15, 1518-1520) and then stored in the drybox over activated molecular sieves.

Formulation and Coating Preparations.

Substrates (SLG slides) were cleaned sequentially with aqua regia, Millipore® water and isopropanol, dried at 110° C., and coated on the non-float surface of the SLG substrate. All formulations and coatings were prepared in a nitrogen-purged drybox. Vials containing formulations were heated and stirred on a magnetic hotplate/stirrer. Coatings were dried in the drybox.

Annealing of Coated Substrates in a Tube Furnace.

Annealings were carried out either under an inert atmosphere (nitrogen or argon) or under an inert atmosphere comprising a chalcogen source (nitrogen/sulfur, argon/sulfur, or argon/selenium). Annealings were carried out in either a single-zone Lindberg/Blue tube furnace (Ashville, N.C.) equipped with an external temperature controller and a one-inch quartz tube, or in a Lindberg/Blue three-zone tube furnace (Model STF55346C) equipped with a three-inch quartz tube. A gas inlet and outlet were located at opposite ends of the tube, and the tube was purged with nitrogen or argon while heating and cooling. The coated substrates were placed on quartz plates inside of the tube.

When annealing under sulfur, a 3-inch long ceramic boat was loaded with 2.5 g of elemental sulfur and placed near the gas inlet, outside of the direct heating zone. The coated substrates were placed on quartz plates inside the tube.

When annealing under selenium, the substrates were placed inside a graphite box (Industrial Graphite Sales, Harvard, IL) with a lid with a center hole in it of 1 mm in diameter. The box dimensions were 5″ length×1.4″ width×0.625″ height with a wall and lid thickness of 0.125″. The selenium was placed in small ceramic boats within the graphite box.

Details of the Procedures Used for Device Manufacture Mo-Sputtered Substrates.

Substrates for photovoltaic devices were prepared by coating an SLG substrate with a 500 nm layer of patterned molybdenum using a Denton Sputtering System. Deposition conditions were: 150 watts of DC Power, 20 sccm Ar, and 5 mT pressure. Alternatively, Mo-sputtered SLG substrates were purchased from Thin Film Devices, Inc. (Anaheim, Calif.).

Cadmium Sulfide Deposition.

CdSO₄ (12.5 mg, anhydrous) was dissolved in a mixture of nanopure water (34.95 mL) and 28% NH₄OH (4.05 mL). Then a 1 mL aqueous solution of 22.8 mg thiourea was added rapidly to form the bath solution. Immediately upon mixing, the bath solution was poured into a double-walled beaker (with 70° C. water circulating between the walls), which contained the samples to be coated. The solution was continuously stirred with a magnetic stir bar. After 23 min, the samples were taken out, rinsed with and then soaked in nanopure water for 1 h. The samples were dried under a nitrogen stream and then annealed under a nitrogen atmosphere at 200° C. for 2 min.

Insulating ZnO and AZO Deposition.

A transparent conductor was sputtered on top of the CdS with the following structure: 50 nm of insulating ZnO (150 W RF, 5 mTorr, 20 sccm) followed by 500 nm of Al-doped ZnO using a 2% Al₂O₃, 98% ZnO target (75 or 150 W RF, 10 mTorr, 20 sccm).

ITO Transparent Conductor Deposition.

A transparent conductor was sputtered on top of the CdS with the following structure: 50 nm of insulating ZnO [100 W RF, 20 mTorr (19.9 mTorr Ar+0.1 mTorr O₂)] followed by 250 nm of ITO [100 W RF, 12 mTorr (12 mTorr Ar+5×10⁻⁶ Torr O₂)]. The sheet resistivity of the resulting ITO layer was around 30 ohms per square.

Deposition of Silver Lines.

Silver was deposited at 150 WDC, 5 mTorr, 20 sccm Ar, with a target thickness of 750 nm.

### Details of X-ray, IV, EQE, and OBIC Analysis.

XRD Analysis.

Powder X-ray diffraction was used to identify crystalline phases. Data were obtained with a Philips X′PERT automated powder diffractometer, Model 3040. The diffractometer was equipped with automatic variable anti-scatter and divergence slits, X′Celerator RTMS detector, and Ni filter. The radiation was CuK(alpha) (45 kV, 40 mA). Data were collected at room temperature from 4 to 120°. 2-theta, using a continuous scan with an equivalent step size of 0.02°, and a count time of from 80 sec to 240 sec per step in theta-theta geometry. Thin film samples were presented to the X-ray beam as made. MDI/Jade software version 9.1 was used with the International Committee for Diffraction Data database PDF4+ 2008 for phase identification and data analysis.

IV Analysis.

Current (I) versus voltage (V) measurements were performed on the samples using two Agilent 5281B precision medium power SMUs in a E5270B mainframe in a four point probe configuration. Samples were illuminated with an Oriel 81150 solar simulator under 1 sun AM 1.5G.

EQE Analysis.

External Quantum Efficiency (EQE) determinations were carried out as described in ASTM Standard E1021-06 (“Standard Test Method for Spectral Responsivity Measurements of Photovoltaic Devices”). The reference detector in the apparatus was a pyroelectric radiometer (Laser Probe (Utica, N.Y.), LaserProbe Model RkP-575 controlled by a LaserProbe Model Rm-6600 Universal Radiometer). The excitation light source was a xenon arc lamp with wavelength selection provided by a monochrometer in conjunction with order sorting filters. Optical bias was provided by a broad band tungsten light source focused to a spot slightly larger than the monochromatic probe beam. Measurement spot sizes were approximately 1 mm×2 mm.

OBIC Analysis.

Optical beam induced current measurements were determined with a purpose-constructed apparatus employing a focused monochromatic laser as the excitation source. The excitation beam was focused to a spot ˜100 microns in diameter. The excitation spot was rastered over the surface of the test sample while simultaneously measuring photocurrent so as to build a map of photocurrent vs position for the sample. The resulting photocurrent map characterizes the photoresponse of the device vs. position. The apparatus can operate at various wavelengths via selection of the excitation laser. Typically, 440, 532 or 633 nm excitation sources were employed.

### Example 1

This example illustrates: (a) the preparation of a molecular precursor to CIS₂; (b) the formation of an annealed film of CIS₂ from the molecular precursor using only an inert gas in the annealing atmosphere; and (c) the production of an active photovoltaic device from an annealed film of the molecular precursor (Example 1A).

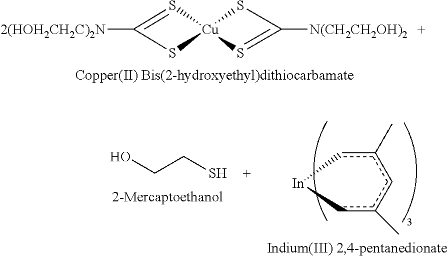

Indium(III) 2,4-pentanedionate (0.6734 g, 1.634 mmol) and copper(II) bis(2-hydroxyethyl)dithiocarbamate (0.6932 g, 1.635 mmol) were placed together in a 40 mL amber septum-capped vial equipped with a stir bar. 4-t-Butylpyridine (1.004 g), 2-aminopyridine (0.5213 g), 2-mercaptoethanol (0.4038 g, 5.168 mmol), and elemental sulfur (0.0518 g, 1.615 mmol) were sequentially added with mixing. The reaction mixture was stirred for ˜72 hr at a first heating temperature of 100° C. Next, the reaction mixture was stirred for ˜24 hr at a second heating temperature of 170° C. The resulting molecular precursor was spun-coated onto an SLG slide at 4000 rpm for 10 seconds. The coating was then dried in the drybox on a hotplate at 170° C. for 15 min. The dried film was annealed under argon in a 3-inch tube furnace by heating to 250° C. at a rate of 15° C./min and then heating to 500° C. at a rate of 2° C./min. The temperature was then held at 500° C. for 1 hr. Analysis of the annealed sample by XRD indicated the presence of CuInS₂ with small amounts of In₂S₃ and CuS₂.

### Example 1A

Example 1 was repeated with the exception that the molecular precursor was deposited on a Mo-patterned SLG slide with a spin-coating speed of 3000 rpm. The Mo layer had a resisitivity of ˜20 ohms/square. Cadmium sulfide, insulating ZnO, ITO, and silver lines were deposited. The device efficiency was 0.200%. Analysis by OBIC at 440 nm gave a photoresponse with J90 of 17 micro-Amp and dark current of 0.15 micro-Amp. The EQE onset was at 880 nm with an EQE of 7.67% at 640 nm.

### Example 2

This example illustrates: (a) the preparation of a molecular precursor to CIS/Se; (b) the formation of an annealed film of CIS₂ and CISe₂ from the molecular precursor using only an inert gas in the annealing atmosphere; (c) the production of an active photovoltaic device from an annealed film of the molecular precursor (Example 2A); and (d) in Example 2B, the formation of an annealed film of the molecular precursor under a sulfur/nitrogen atmosphere with large grain sizes (according to scanning electron microscopy), and a crystalline composition consisting only of CIS and CIS/Se (according to XRD).

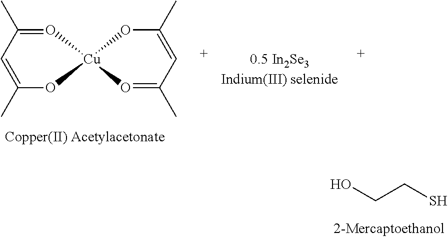

Copper(II) acetylacetonate (0.4317 g, 1.649 mmol), indium(III) selenide (0.3898 g, 0.836 mmol), 1.5 g of a 2:1 solution of 4-t-butylpyridine and 2-aminopyridine, 2-mercaptoethanol (0.2700 g, 3.456 mmol), and sulfur (0.0256 g, 0.7983 mmol) were combined and heated following the procedures of Example 1. The resulting molecular precursor was spun-coated onto an SLG slide at 2,250 rpm for 10 sec. The coating was then dried in the drybox on a hotplate at 170° C. for 15 min and then at 230° C. for 5 min. The coating (3,250 rpm for 10 sec) and drying procedures were repeated. The dried film was then annealed under argon in a 3-inch tube furnace by heating to 250° C. at a rate of 15° C./min and then heating to 500° C. at a rate of 2° C./min. The temperature was then held at 500° C. for 1 hr. Analysis of the annealed sample by XRD indicated the presence of CuInSe₂ Cu_{0.79}In_{0.78}Se_{1.8} and two forms of CuInS₂ along with small amounts of CuS, Se, and S₆.

### Example 2A

Example 2 was repeated, but the molecular precursor was deposited on a Mo-patterned SLG slide. Cadmium sulfide, insulating ZnO, ITO, and silver lines were deposited. The Mo layer had a resisitivity of ˜20 ohms/square. The device efficiency was 0.066%. Analysis by OBIC at 440 nm gave a photoresponse with J90 of 4.1 micro-Amp and dark current of 0.23 micro-Amp. The EQE onset was at 880 nm with an EQE of 5.76% at 640 nm.

### Example 2B

A molecular precursor was prepared and heated as in Example 2. The resulting molecular precursor was spun-coated onto an SLG slide at 450 rpm for 3 sec and then at 3000 rpm for 4 sec. The coating was then dried in the drybox on a hotplate at 65° C. for several hours and then at 170° C. for ˜0.5 hr. The coating (3,250 rpm for 10 sec) and drying procedures were repeated. The dried film was then annealed under nitrogen in a 3-inch tube by raising the temperature to 500° C. at a rate of 15° C./min and then holding the temperature at 500° C. for 1 hr. The film was then further annealed at 550° C. for 0.5 hr under a nitrogen/sulfur atmosphere in a one-inch tube. Analysis of the annealed film by XRD indicated the presence of only two crystalline phases: CuIn_{1.93}Se_{3.5} and Roquesite CuInS₂. Analysis of the annealed film by SEM indicated the presence of grains larger than 1 micron.

### Example 3

Examples 3 and 3A illustrate the formation of molecular precursor inks to CIS. Annealed films prepared from both of the inks have a crystalline composition consisting only of CIS₂, according to XRD. Both films were formed under an atmosphere consisting only of an inert gas.

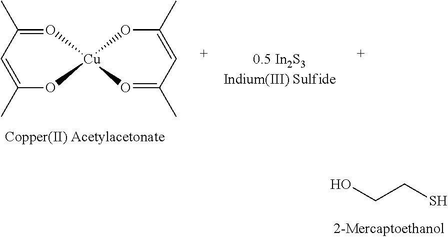

Copper(II) acetylacetonate (0.4270 g, 1.631 mmol), indium(III) sulfide (0.2659 g, 0.816 mmol), 1.5 g of a 3:2 solution of 5-ethyl-2-methylpyridine and 2-aminopyridine, 2-mercaptoethanol (0.2934 g, 3.755 mmol), and sulfur (0.0528 g, 1.646 mmol) were combined and heated following the procedures of Example 1. The resulting molecular precursor was spun-coated onto an SLG slide at 2,250 rpm for 10 sec. The coating was then dried in the drybox on a hotplate at 170° C. for 15 min and then at 230° C. for 5 min. The coating (3,500 rpm for 10 sec) and drying procedures were repeated. The dried film was then annealed under argon in a 3-inch tube furnace by heating to 250° C. at a rate of 15° C./min and then heating to 500° C. at a rate of 2° C./min. The temperature was then held at 500° C. for 1 hr. Analysis of the annealed sample by XRD indicated the presence of one crystalline phase: CIS₂.

### Example 3A

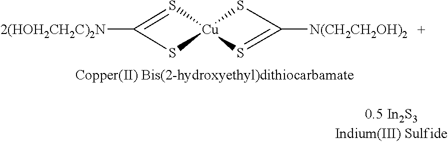

Copper(II) bis(2-hydroxyethyl)dithiocarbamate (0.6924 g, 1.633 mmol), indium(III) sulfide (0.2659 g, 0.816 mmol), 1.00 g 4-t-butylpyridine, 0.5023 g of 2-aminopyridine, and sulfur (0.0533 g, 1.662 mmol) were combined and heated following the procedures of Example 1. The resulting molecular precursor was spun-coated onto a SLG slide at 3,000 rpm for 10 sec. The coating was then dried in the drybox on a hotplate at 170° C. for 15 min and then at 230° C. for 5 min. The coating (3,500 rpm for 8 sec) and drying procedures were repeated. The dried film was then annealed under argon in a 3-inch tube furnace by heating to 250° C. at a rate of 15° C./min and then heating to 500° C. at a rate of 2° C./min. The temperature was then held at 500° C. for 1 hr. Analysis of the annealed sample by XRD indicated the presence of one crystalline phase: CIS₂.

### Example 4

Examples 4A-4D illustrate the formation of molecular precursor inks to CIS/Se utilizing either In₂S₃ or In₂Se₃, Cu(I) acetate, diethylselenide, and selenium or sulfur powder. Butanethiol was used as an additive in the inks, and the films were annealed under a Se/argon atmosphere. In Examples 4A-4C, the phase of the resulting CIS/Se varied from tetragonal to cubic to a mixture of cubic and tetragonal. In Example 4D, an active device from an ink containing In₂S₃ was formed.

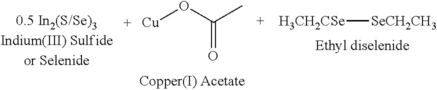

### Example 4A

In the drybox, copper(I) acetate (0.4000 g, 3.263 mmol) and indium(III) selenide (0.7636 g, 1.637 mmol) were placed together with a stir bar in a 40 mL vial. Solvent (−1.5 g of 3,5-lutidine) and ethyl diselenide (0.3666 g, 1.697 mmol) were placed together in a 20 mL vial. Both vials were cooled to −25° C. in the drybox freezer. The cold ethyl diselenide solution was added to the mix of copper and indium reagents. The reaction mixture was stirred as it was allowed to warm to room temperature. Chalcogen powder (selenium, 0.3666 g, 1.697 mmol) was added to the reaction mixture, which was then capped with a vented septum and stirred for more than one week at 100° C. Additional solvent (2 g of 3,5-lutidine) was added, and the reaction mixture was then stirred for 4 days at 150° C. The reaction mixture was allowed to cool to room temperature. Butanethiol (0.42 g) was added, and the resulting ink was stirred several days at room temperature and then filtered twice through small plugs of glass wool in pipettes. A small portion of the ink was drawn into a pipette and spread onto a Mo-sputtered SLG substrate. After allowing the ink to sit on the substrate for ˜2 min, it was spun at 620 rpm for 3 sec. The coating was then dried in the drybox at 175° C. for ˜30 min on a hotplate. The same coating and drying procedure was repeated two times to form a second and third coated layer. The resulting 3-layer coating was dried at 250° C. for ˜30 min. The coated substrate was placed in a graphite box along with four other coated substrates and three ceramic boats containing a total of 150 mg of Se pellets. The box was placed in a 3-inch tube furnace which was evacuated and then placed under argon. The temperature was increased to 585° C. Once it reached the set point, the furnace was allowed to cool to 500° C. and held at 500° C. for 30 min. The XRD of the annealed film had peaks for Mo, trace MoSe₂, and tetragonal CuIn(S/Se)₂ with a S/Se ratio of 1.7/98.3 and a coherent domain size of 87.1+/−1.3 nm.

### Example 4B

An ink was prepared using the reagents and procedure of Example 4A with the exception that a 2:1 mixture of 3,5-lutidine/3-aminopyridine was used as the solvent. Using the coating procedure of Example 4A, two-layer coatings were produced on a number of Mo-sputtered SLG substrates. One of the coated substrates was dried at 250° C. for ˜30 min and then placed in a graphite box, along with four other coated substrates and three ceramic boats containing a total of 150 mg of Se pellets. The box was placed in a 3-inch tube furnace which was evacuated and then placed under argon. The temperature was increased to 600° C. Once it reached the set point, the furnace lid was opened briefly to cool the temperature to 500° C. The lid was closed and the furnace was held at 500° C. for 30 min. The XRD of the annealed film had peaks for Mo, trace MoSe₂, tetragonal CuInSe₂, cubic Cu_{0.5}In_{0.5}Se, a S/Se ratio of approx. 0/100, and a coherent domain size of greater than 100 nm.

### Example 4C

An ink was prepared using the reagents and procedures of Example 4A with the following exceptions: In₂₅₃ was used as the indium source, a mixture of 1.5 g of pyridine and 0.165 g of 3-aminopyridine was used as the solvent, the chalcogen powder consisted of sulfur, and the ink was heated at 100° C. for one week, but not to 150° C. The coating and annealing procedure of Example 4A was followed with the following three exceptions: (1) A 2-layer coated substrate was formed and was dried at 175° C. for ˜30 min. (2) A total of only 5-10 mg of selenium were placed in two ceramic boats inside of the graphite box. (3) The furnace temperature was increased to 575° C., held there for 20 min, and then allowed to cool to room temperature. The XRD of the annealed film had peaks for Mo, cubic Cu_{0.5}In_{0.5}Se, and possibly trace CuO, and a coherent domain size of 16.3+/−0.2 nm. The S/Se ratio was 13.8/86.2.

### Example 4D

The procedure of Example 4C was followed with the following two exceptions: (1) Three ceramic boats containing a total of 150 mg of Se pellets were placed in the graphite box. (2) During the anneal, the furnace temperature was increased to 585° C. Once it reached the set point, the tube was allowed to cool to 500° C. and held at 500° C. for 30 min. The annealed film was brought into the drybox and heated to 300° C. on a hotplate for 45 min. Cadmium sulfide (the above procedure was repeated two times), insulating ZnO, ITO, and silver lines were deposited on the annealed film. The device efficiency was 0.106%.

What is claimed is:

1. A molecular precursor to CIGS/Se comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof;
provided that: if the copper source is copper sulfide or copper selenide, and the indium source is indium sulfide or indium selenide, then the vehicle does not comprise hydrazine.

2. The molecular precursor of claim 1, wherein the molecular precursor has been heat-processed at temperature of greater than about 90° C.

3. The molecular precursor of claim 1, wherein the molar ratio of Cu:(In+Ga) is about 1.

4. The molecular precursor of claim 1, wherein the molar ratio of total chalcogen to (Cu+In+Ga) in the molecular precursor is at least about 1.

5. The molecular precursor of claim 1, wherein the molecular precursor further comprises a chalcogen compound.

6. The molecular precursor of claim 5, wherein the chalcogen compound is selected from the group consisting of: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof,
wherein each Z is independently selected from the group consisting of: H, NR⁴₄, and SiR⁵₃;
wherein each R¹ and R⁵ is independently selected from the group consisting of: hydrocarbyl and O-, N-, S-, halogen- or tri(hydrocarbyl)silyl-substituted hydrocarbyl;
each R² is independently selected from the group consisting of hydrocarbyl, O-, N-, S-, Se-, halogen-, or tri(hydrocarbyl)silyl-substituted hydrocarbyl, and O-, N-, S-, or Se-based functional groups; and
each R⁴ is independently selected from the group consisting of hydrogen, O-, N-, S-, Se-, halogen- or tri(hydrocarbyl)silyl-substituted hydrocarbyl, and O-, N-, S-, or Se-based functional groups.

7. The molecular precursor of claim 1, wherein the nitrogen-, oxygen-, carbon-, sulfur-, or selenium-based organic ligands are selected from the group consisting of: amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates.

8. The molecular precursor of claim 1, wherein the ink further comprises elemental sulfur, elemental selenium, or a mixture of elemental sulfur and selenium, and the molar ratio of elemental (S+Se) is about 0.2 to about 5 relative to the copper source.

9. A coated substrate comprising:
A) a substrate; and
B) at least one layer disposed on the substrate comprising a molecular precursor to CIGS/Se comprising:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof;
wherein at least one of the copper or indium sources comprises complexes of nitrogen-, oxygen-, carbon-, sulfur-, or selenium-based organic ligands.

10. The coated substrate of claim 9, wherein the molar ratio of Cu:(In+Ga) is about 1.

11. The coated substrate of claim 9, wherein the molar ratio of total chalcogen to (Cu+In+Ga) in the molecular precursor is at least about 1.

12. The coated substrate of claim 9, wherein the molecular precursor further comprises a chalcogen compound.

13. A process comprising disposing a molecular precursor to CIGS/Se onto a substrate to form a coated substrate, wherein molecular precursor comprises:
i) a copper source selected from the group consisting of copper complexes of nitrogen-, oxygen-, carbon-, sulfur-, or selenium-based organic ligands, copper sulfides, copper selenides, and mixtures thereof;
ii) an indium source selected from the group consisting of indium complexes of nitrogen-, oxygen-, carbon-, sulfur-, or selenium-based organic ligands, indium sulfides, indium selenides, and mixtures thereof;
iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
iv) a vehicle, comprising a liquid chalcogen compound, a solvent, or a mixture thereof;
provided that if the copper source is copper sulfide or copper selenide, and the indium source is indium sulfide or indium selenide, then the vehicle does not comprise hydrazine.

14. The process of claim 13, wherein the molar ratio of Cu:(In+Ga) is about 1.

15. The process of claim 13, wherein the molecular precursor further comprises a chalcogen compound.
